(19) United States
(12) Patent Application Publication
(10) Pub. No.: US 2015/0214458 A1
(43) Pub. Date: Jul. 30, 2015

(54) THERMOELECTRIC GENERATOR SYSTEM FOR INTERCOOLER COUPLED TO TURBOCHARGER

(71) Applicant: General Electric Company, Schenectady, NY (US)

(72) Inventors: Pavan Chakravarthy Nandigama, Bangalore (IN); Amit Shrivastava, Bangalore (IN)

(73) Assignee: General Electric Company, Schenectady, NY (US)

(21) Appl. No.: 14/164,464

(22) Filed: Jan. 27, 2014

(51) Int. Cl. H01L 35/30; F02B 29/04

(52) U.S. Cl. CPC H01L 35/30; F02B 29/0406

(57) ABSTRACT

A thermoelectric generator system for use between gases from a compressor stage of a turbocharger and a heat transfer fluid of an intercooler that treats the gases. In one version, the system may include a first terminal in thermal contact with gases from the compressor stage of the turbocharger to be treated by the intercooler; a second terminal in thermal contact with a heat transfer fluid for use in the intercooler; and a thermoelectric material between the first terminal and the second terminal, the thermoelectric generator converting a temperature difference between the gases and the heat transfer fluid to an electric current. A controller may be provided for controlling a current flow transmitted from the thermoelectric material to a load. A related intercooler system and engine system are also provided.

### BACKGROUND OF THE INVENTION

1. Technical Field

The disclosure relates generally to thermoelectric generators, and more particularly, to a thermoelectric generator system for use between gases from a compressor stage of a turbocharger and a heat transfer fluid of an intercooler that treats the gases. A related intercooler system and engine system are also provided.

2. Related Art

Thermoelectric generators have been used to convert waste heat in internal combustion engines into electricity based on the Seebeck Effect. Typically, such a generator includes a heat exchanger for the cold side and a heat exchanger for the hot side, and thermoelectric materials between the heat exchangers. The waste heat is taken from either the engine's exhaust or the engine's coolant. By generating electricity from waste heat, the generator can increase fuel efficiency.

### BRIEF DESCRIPTION OF THE INVENTION

A first aspect of the disclosure provides a thermoelectric generator system for use with an intercooler that heats or cools gases exiting a compressor stage of a turbocharger, the thermoelectric generator comprising: a first terminal in thermal contact with gases from the compressor stage of the turbocharger to be treated by the intercooler; a second terminal in thermal contact with a heat transfer fluid for use in the intercooler; and a thermoelectric material between the first terminal and the second terminal, the thermoelectric generator converting a temperature difference between the gases and the heat transfer fluid to an electric current.

A second aspect of the disclosure provides an intercooler system for heating or cooling gases exiting a compressor stage of a turbocharger, the intercooler system comprising: a thermal transfer interface in which the gases exiting the compressor stage of the turbocharger come into thermal contact with a heat transfer fluid to heat or cool the gases; and a thermoelectric generator having a first terminal in thermal contact with the gases, a second terminal in thermal contact with the heat transfer fluid and a thermoelectric material between the first terminal and the second terminal, the thermoelectric generator converting a temperature difference between the gases and the heat transfer fluid to an electric current.

A third aspect of the disclosure provides an engine system comprising: an engine having an exhaust; a turbocharger receiving at least a portion of the exhaust for compressing gases entering a compressor stage of the turbocharger; an intercooler for heating or cooling gases exiting the compressor stage of the turbocharger prior to passage to the engine, the intercooler including a thermal transfer interface in which the gases exiting the compressor stage of the turbocharger come into thermal contact with a heat transfer fluid to heat or cool the gases; and a thermoelectric generator having a first terminal in thermal contact with the gases, a second terminal in thermal contact with the heat transfer fluid and a thermoelectric material between the first terminal and the second terminal, the thermoelectric generator converting a temperature difference between the gases and the heat transfer fluid to an electric current.

The illustrative aspects of the present disclosure are designed to solve the problems herein described and/or other problems not discussed.

### BRIEF DESCRIPTION OF THE DRAWINGS

These and other features of this disclosure will be more readily understood from the following detailed description of the various aspects of the disclosure taken in conjunction with the accompanying drawings that depict various embodiments of the disclosure, in which:

FIG. 1 shows a block diagram of a thermoelectric generator system, an intercooler system and an engine system according to embodiments of the invention.

FIG. 2 shows a block diagram of a detail of the thermoelectric generator used in the various systems according to embodiments of the invention.

It is noted that the drawings of the disclosure are not to scale. The drawings are intended to depict only typical aspects of the disclosure, and therefore should not be considered as limiting the scope of the disclosure. In the drawings, like numbering represents like elements between the drawings.

### DETAILED DESCRIPTION OF THE INVENTION

As indicated above, the disclosure provides thermoelectric generator system for use between gases from a compressor stage of a turbocharger and a heat transfer fluid of an intercooler that treats the gases. A related intercooler system and engine system are also provided.

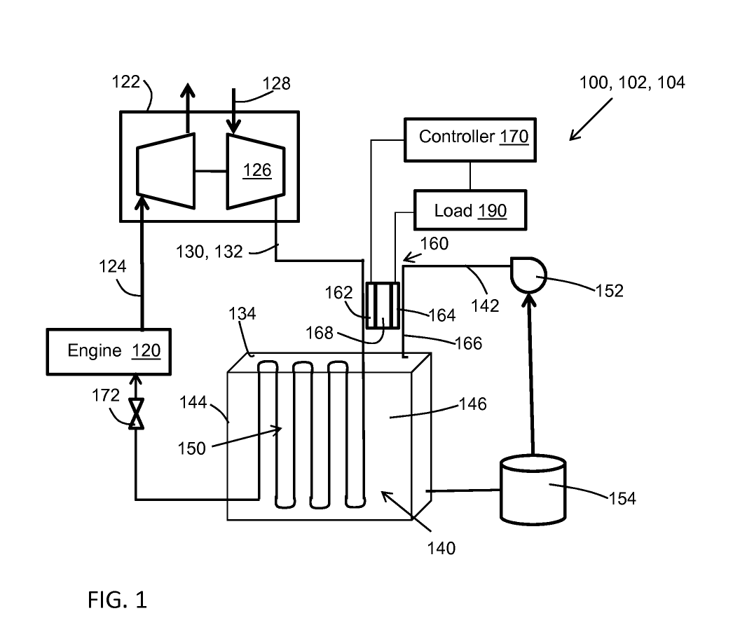

Referring to FIG. 1, a block diagram of a thermoelectric generator system 100, an intercooler system 102 and an engine system 104 according to embodiments of the invention are illustrated. Engine system 104 includes an engine 120 of any type including but not limited to a gas internal combustion engine, a diesel engine, a gasoline engine, gas turbines, etc. A turbocharger 122 is operatively coupled to engine 120. Turbocharger 122 may include any now known or later developed turbocharging system capable of using a flow of exhaust 124 from engine 120 to create a compressed gas flow for later use by engine 120, e.g., in a combustion cycle. As understood in the art, turbocharger 122 receives a flow of exhaust 124 from engine 120, e.g., via a conduit, and takes at least a portion of exhaust flow to power a compressor stage 126. Compressor stage 126 takes in gases, e.g., air or charge (air mixed with fuel) via an intake 128 and compresses the gases. As the gases are compressed, the gases typically increase in temperature, e.g., from 150° C. to 300° C. Gases 130 at the raised temperature created by compressor stage 126 are typically too hot to be used in engine 120 in an efficient manner.

In order to decrease the temperature of gases 130, the gases in a compressed state are communicated, e.g., via a conduit 132, to intercooler 134 for cooling treatment. That is, intercooler 134 cools gases 130 exiting compressor stage 126 of turbocharger 122. As known in the art, intercooler 122 may also act to heat gases 130 in certain instances. Intercooler 134 includes a thermal transfer interface 140 in which gases 130 exiting compressor stage 126 of turbocharger 122 come into thermal contact with a heat transfer fluid 142 to heat or cool the gases. Thermal transfer interface 140 may include a chamber 144 for receiving gases 130. An interior 146 of chamber 144 includes a plurality of tubes 150 through which the gases flow. Heat transfer fluid 142 fills chamber 144 and surrounds plurality of tubes 150 as the heat transfer fluid 142 passes through the chamber. Thermal transfer interface 140, also referred to as a heat exchanger, may include both a shell and tube type device. Heat transfer fluid 142 may be circulated in a known fashion via a pump 152 from a reservoir 154 into and out of chamber 144 via a number of conduits. Heat transfer fluid 142 may include any now known or later developed fluid capable of heat transfer from plurality of tubes 150 including but not limited to: air, water, antifreeze, or combinations thereof. In one embodiment, heat transfer fluid may include an antifreeze to improve heat transfer and other capabilities of the fluid. If necessary, heat transfer fluid 142 may have heat transferred therefrom in any known fashion, e.g., a radiator, etc.

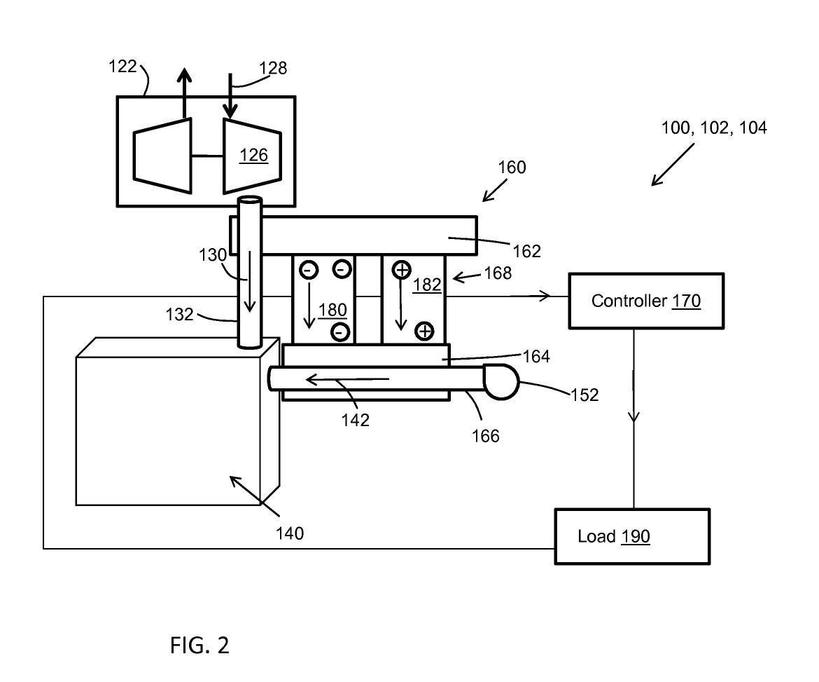

Referring to FIGS. 1 and 2 collectively, each system 100, 102, 104 includes a thermoelectric generator 160 that generates electricity from the temperature difference between compressed gases 130 and heat transfer fluid 142. FIG. 2 shows a block diagram of a detail of the thermoelectric generator 160 used in the various systems according to embodiments of the invention (engine 120 has been removed for clarity). The temperature difference may vary depending on the type, size, fuel of engine 120, among other factors. Thermoelectric generator 160 includes a first terminal 162 in thermal contact with gases 130 from compressor stage 126 of turbocharger 122 to be treated by intercooler 134, and a second terminal 164 in thermal contact with heat transfer fluid 142 for use in intercooler 134. Each terminal 162, 164 may include any structure or material capable of transferring heat from the respective flow of gas or heat transfer fluid. In one embodiment, first terminal 162 is in thermal contact with a conduit 132 carrying gases 130 from compressor stage 126 of turbocharger 122 to intercooler 134. First terminal 162 may include an elongated ring or band that encircles conduit 132 or otherwise is capable of absorbing heat therefrom, or otherwise, from gases 130. First terminal 162 may be thermally coupled to conduit 132, for example, at a solid end of high conductivity wrapping between insulation and hot conduit 132; however, other locations are also possible. Similarly, second terminal 164 is in thermal contact with a conduit 166 carrying heat transfer fluid 142 to intercooler 134. Second terminal 164 may include an elongated ring or band that encircles conduit 166 or otherwise is capable of absorbing heat therefrom, or otherwise, from heat transfer fluid 142. Second terminal 164 may be coupled to conduit 166, for example, at a solid end of high conductivity wrapping between insulation and cooler conduit 166; however, other locations are also possible. Terminals 162, 164 may be made of any now known or later developed heat exchanger material having a high thermal conductivity such as but not limited to metals such as copper, aluminum, etc.

Referring to FIG. 1, thermoelectric generator 160 also includes a thermoelectric material 168 between terminals 162, 164. Thermoelectric material 168 may include any now known or later developed thermoelectric substance such as p-type and n-type semiconductors 180, 182 such as, depending on temperature: bismuth telluride (Bi₂Te₃), lead telluride (PbTe), calcium manganese oxide, or combinations thereof. When a temperature difference is placed across terminals 162, 164 and thermoelectric material 168, electricity is generated through the Seebeck effect, also known as the thermoelectric effect. That is, when hot gases 130 from compressor stage 126 of turbocharger 122 come into thermal contact with first terminal 162, heat passes from the terminal and into thermoelectric material 168, causing charge carriers of thermoelectric material 168 (semiconductors) to diffuse from first terminal 162 to second terminal 164. The build-up of charge carriers creates a net charge, resulting in an electrostatic potential as the heat transfer drives the current. Current is carried from terminals 162, 164 to a load 190, or where provided, a controller 170 by wires. In one example, with a gas 130 temperature of approximately 280° C. or more, the temperature difference between first and second terminals may be approximately 250° C., which may generate approximately 24 W of electricity.

Thermoelectric generator 160 may also optionally include a controller 170 for controlling a current flow transmitted from thermoelectric material 168 to a load 190, i.e., as it is generated by a temperature difference between gases 130 and heat transfer fluid 142. Controller 170 may include any now known or later developed electronic controller for controlling the distribution of electricity, where simple connection to load 190 is inadequate. Electricity generated may be consumed by any variety of electricity consuming load(s) 190, e.g., machine controls, pumps, starters, etc., that are part of systems 100, 102, 104.

Intercooler system 102 for heating or cooling gases exiting a compressor stage 126 of a turbocharger 122, according to embodiments of the invention, may include thermal transfer interface 140 in which the gases exiting the compressor stage of the turbocharger come into thermal contact with heat transfer fluid 142 to heat or cool the gases. Intercooler system 102 may also include thermoelectric generator 160 having first terminal 162 in thermal contact with the gases and second terminal 162 in thermal contact with the heat transfer fluid 142, and thermoelectric material 168 therebetween. Also, where necessary, controller 170 may control a current flow transmitted from thermoelectric material 168.

Engine system 104, according to embodiments of the invention, may include engine 120 having exhaust 124, as discussed previously, and turbocharger 122 receiving at least a portion of the exhaust for compressing gases entering compressor stage 126 of the turbocharger. Engine system 104 may also include intercooler 134 for heating or cooling gases 130 exiting compressor stage 126 of the turbocharger prior to passage to the engine. Intercooler 134 includes thermal transfer interface 140 in which the gases exiting the compressor stage of the turbocharger come into thermal contact with heat transfer fluid 142 to heat or cool the gases. In a known fashion, a throttle valve 172 (FIG. 1) may be provided to control the amount of cooled gases input to engine 120. Engine system 104 also includes thermoelectric generator 160 having first terminal 162 in thermal contact with the gases and second terminal 162 in thermal contact with the heat transfer fluid 142, and thermoelectric material 168 therebetween. As noted above, where necessary, controller 170 may control a current flow transmitted from thermoelectric material 168.

The terminology used herein is for the purpose of describing particular embodiments only and is not intended to be limiting of the disclosure. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

The corresponding structures, materials, acts, and equivalents of all means or step plus function elements in the claims below are intended to include any structure, material, or act for performing the function in combination with other claimed elements as specifically claimed. The description of the present disclosure has been presented for purposes of illustration and description, but is not intended to be exhaustive or limited to the disclosure in the form disclosed. Many modifications and variations will be apparent to those of ordinary skill in the art without departing from the scope and spirit of the disclosure. The embodiment was chosen and described in order to best explain the principles of the disclosure and the practical application, and to enable others of ordinary skill in the art to understand the disclosure for various embodiments with various modifications as are suited to the particular use contemplated.

What is claimed is:

1. A thermoelectric generator system for use with an intercooler that heats or cools gases exiting a compressor stage of a turbocharger, the thermoelectric generator comprising:
a first terminal in thermal contact with gases from the compressor stage of the turbocharger to be treated by the intercooler;
a second terminal in thermal contact with a heat transfer fluid for use in the intercooler; and
a thermoelectric material between the first terminal and the second terminal for converting a temperature difference between the gases and the heat transfer fluid to an electric current.

2. The thermoelectric generator system of claim 1, wherein the heat transfer fluid includes an antifreeze.

3. The thermoelectric generator system of claim 1, wherein the first terminal is in thermal contact with a conduit carrying the gases from the compressor stage of the turbocharger to the intercooler.

4. The thermoelectric generator system of claim 1, wherein the second terminal is in thermal contact with a conduit carrying the heat transfer fluid to the intercooler.

5. The thermoelectric generator system of claim 1, further comprising a controller for controlling a current flow transmitted from the thermoelectric material to a load.

6. An intercooler system for heating or cooling gases exiting a compressor stage of a turbocharger, the intercooler system comprising:
a thermal transfer interface in which the gases exiting the compressor stage of the turbocharger come into thermal contact with a heat transfer fluid to heat or cool the gases; and
a thermoelectric generator having a first terminal in thermal contact with the gases, a second terminal in thermal contact with the heat transfer fluid and a thermoelectric material between the first terminal and the second terminal, the thermoelectric generator converting a temperature difference between the gases and the heat transfer fluid to an electric current.

7. The intercooler system of claim 6, wherein the thermal transfer interface includes a chamber for receiving the gases, the interior of the chamber including a plurality of tubes through which the gases flow, wherein the heat transfer fluid fills the chamber and surrounds the plurality of tubes as the heat transfer fluid passes through the chamber.

8. The intercooler system of claim 6, wherein the thermal transfer liquid includes an antifreeze.

9. The intercooler system of claim 6, wherein the gases include air or charge.

10. The intercooler system of claim 6, wherein the first terminal is in thermal contact with a conduit carrying the gases from the compressor stage of the turbocharger to the intercooler.

11. The intercooler system of claim 6, wherein the second terminal is in thermal contact with a conduit carrying the heat transfer fluid to the intercooler.

12. The intercooler system of claim 6, further comprising a controller for controlling a current flow transmitted from the thermoelectric material to a load.

13. An engine system comprising:
an engine having an exhaust;
a turbocharger receiving at least a portion of the exhaust for compressing gases entering a compressor stage of the turbocharger;
an intercooler for heating or cooling gases exiting the compressor stage of the turbocharger prior to passage to the engine, the intercooler including a thermal transfer interface in which the gases exiting the compressor stage of the turbocharger come into thermal contact with a heat transfer fluid to heat or cool the gases; and
a thermoelectric generator having a first terminal in thermal contact with the gases, a second terminal in thermal contact with the heat transfer fluid and a thermoelectric material between the first terminal and the second terminal, the thermoelectric generator converting a temperature difference between the gases and the heat transfer fluid to an electric current.

14. The engine system of claim 13, wherein the thermal transfer liquid includes an antifreeze.

15. The engine system of claim 13, wherein the gases include air or charge.

16. The engine system of claim 13, wherein the first terminal is in thermal contact with a conduit carrying the gases from the compressor stage of the turbocharger to the intercooler.

17. The engine system of claim 13, wherein the second terminal is in thermal contact with a conduit carrying the heat transfer fluid to the intercooler.

18. The engine system of claim 13, further comprising a throttle valve controlling flow of the gases from the intercooler to the engine.

19. The engine system of claim 13, further comprising a controller for controlling a current flow transmitted from the thermoelectric material to a load.
